(19) United States
(12) Patent Application Publication
(10) Pub. No.: US 2014/0030557 A1
(43) Pub. Date: Jan. 30, 2014

(54) CURRENT BREAKING DEVICE AND BATTERY PACK HAVING THE SAME

(71) Applicant: SAMSUNG SDI CO., LTD., Yongin-si, Gyeonggi-do (KR)

(72) Inventor: Youngjun Kim, Yongin-si (KR)

(73) Assignee: SAMSUNG SDI CO., LTD., Yongin-si (KR)

(21) Appl. No.: 13/678,081

(22) Filed: Nov. 15, 2012

(30) Foreign Application Priority Data
Jul. 24, 2012 (KR) 10-2012-0080620

(51) Int. Cl. H01M 10/42; H05K 1/18; H05K 1/11

(52) U.S. Cl. CPC H01M 10/425; H05K 1/11; H05K 1/18
USPC 429/7; 361/748; 429/7

(57) ABSTRACT

A battery pack includes a protective circuit configured to operate when a voltage of the battery is lower than a first voltage or higher than a second voltage or when a current greater than a particular current is detected, and the protective circuit includes a circuit board including a wire pattern, a current breaking device electrically connected to the wire pattern and formed patternwise on the circuit board, and a controller configured to control the current breaking device.

### CROSS-REFERENCE TO RELATED APPLICATION

This application claims priority to and the benefit of Korean Patent Application No. 10-2012-0080620 filed on Jul. 24, 2012, in the Korean Intellectual Property Office, the disclosure of which is incorporated in its entirety herein by reference.

### BACKGROUND

1. Field

Aspects of embodiments of the present invention relate to a current breaking device and a battery pack having the same.

2. Description of the Related Art

In general, a battery pack includes a charger/discharger circuit and a protective circuit for safely protecting a battery cell from over-charge and over-discharge of the battery cell or an external short.

When an over-voltage or over-current is generated, the protective circuit temporarily stops charging or discharging using a charge switch or a discharge switch or permanently disables charging or discharging by shutting down a fuse. However, the conventional protective circuit requires a separate component, the fuse, as a current breaking device, additional cost for the fuse may be added to the manufacturing cost, so that the overall manufacturing cost may increase.

### SUMMARY

An aspect of an embodiment of the present invention is directed toward a current breaking device, which can reduce manufacturing cost by using a pattern of a circuit board, instead of a separately provided conventional fuse, as an over-voltage and over-current protection or preventing element, and a battery pack having the same.

According to at least one embodiment of the present invention, a current breaking device on a circuit board and connected to a battery is provided, the current breaking device including a first land and a second land spaced apart from each other and electrically connected to a current path, a fuse pattern on the first land and the second land and electrically connecting the first land and the second land, a current transfer pattern electrically connecting the first land to the second land in parallel with the fuse pattern, a heat concentration unit adjacent the fuse pattern and connected to the current transfer pattern, an insulation film between the heat concentration unit and the fuse pattern, and a switch electrically connected to the heat concentration unit.

The switch may be configured to be turned on when a voltage of the battery is lower than a first voltage or higher than a second voltage or when a current of the high current path is larger than a particular current. The heat concentration unit may be configured to generate resistance heat to melt the fuse pattern to electrically disconnect the current path. The fuse pattern may be made of a first material, and the first and second land may be made of a second material respectively, the first material being different from the second material. The first land, the second land and the current transfer pattern may have higher melting temperatures than the fuse pattern. The fuse pattern may be wider than the current transfer pattern. The heat concentration unit may have a zigzag plane. The insulation film may be thermally conductive and may be made of resin or plastic. The insulation film may surround the heat concentration unit and may be interposed between the first land and the second land. The switch may include a first electrode electrically connected to the heat concentration unit and a second electrode electrically connected to a ground terminal.

According to at least one embodiment, a current breaking device is provided, the current breaking device including a heat generation unit formed patternwise in a current path disposed on a circuit board and including a resistor, and a fuse pattern adjacent the heat generation unit and formed patternwise in the current path disposed on the circuit board, the fuse pattern being electrically connected in series with the heat generation unit in the current path.

The heat generation unit may be configured to generate heat using resistive heating derived from a current flowing through the heat generation unit. The heat generation unit may be configured to melt the fuse pattern using the resistive heating. The heat generation unit may be made of a first material, and the fuse pattern may be made of a second material, the first material being different from the second material.

The heat generation unit may be coupled between a battery side and the fuse pattern, and the fuse pattern may be coupled between the heat generation unit and a terminal ; or the heat generation unit may be coupled between the terminal and the fuse pattern, and the fuse pattern may be coupled between the heat generation unit and the battery. The heat generation unit may include a first heat generation unit and a second heat generation unit, and the fuse pattern may be between the first heat generation unit and the second heat generation unit.

According to at least one embodiment, a battery pack is provided, including a rechargeable battery and a protective circuit configured to operate when a voltage of the battery is lower than a first voltage or higher than a second voltage or when a current greater than a particular current is detected, wherein the protective circuit includes a circuit board including a wire pattern, a current breaking device electrically connected to the wire pattern and formed patternwise on the circuit board, and a controller configured to control the current breaking device.

The current breaking device may include a first land and a second land spaced apart from each other and connected to a high current path, a fuse pattern formed on the first land and the second land and electrically connecting the first land and the second land, a current transfer pattern electrically connecting the first land and the second land in parallel with the fuse pattern, a heat concentration unit formed adjacent the fuse pattern and electrically connected to the current transfer pattern, an insulation film between the heat concentration unit and the fuse pattern, and a switch having a first electrode connected to the heat concentration unit and a second electrode connected to a ground terminal and configured to be turned on by the controller. The current breaking device may be configured to turn on the switch to connect the heat concentration unit to the ground terminal, so that resistive heating derived from the current flowing through the current breaking device is generated. The current breaking device may be configured to melt the fuse pattern using the resistive heating to electrically disconnect the current path of the wire pattern.

According to at least one embodiment of the present invention, a pattern of a circuit board, instead of a comparable fuse that is separately provided, is used as an over-voltage and over-current preventing element, thereby reducing manufacturing costs.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain principles of the present disclosure.

In the drawings:

FIG. 1A is a schematic diagram illustrating a current breaking device according to one embodiment of the present invention and a battery pack including the same, and FIG. 1B is an enlarged view of a portion ‘1b’ of FIG. 1A;

FIGS. 2A and 2B are cross-sectional views illustrating states before and after an operation of the current breaking device shown in FIG. 1, according to one embodiment of the present invention;

FIG. 3A is a schematic diagram illustrating a current breaking device according to one embodiment of the present invention and a battery pack including the same, and FIG. 3B is an enlarged view of a portion ‘3b’ of FIG. 3A;

FIGS. 4A and 4B are a circuit diagram and a cross-sectional view schematically illustrating a current breaking device according to one embodiment of the present invention, and a battery pack including the same;

FIGS. 5A and 5B are a circuit diagram and a cross-sectional view schematically illustrating a current breaking device according to one embodiment of the present invention, and a battery pack including the same; and

FIGS. 6A and 6B are a circuit diagram and a cross-sectional view schematically illustrating a current breaking device according to one embodiment of the present invention, and a battery pack including the same.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the disclosure to those skilled in the art. Like reference numerals refer to like elements throughout. It will be understood that when an element or layer is referred to as being “connected to” another element or layer, it can be directly connected to the other element or layer, or intervening elements or layers may be present.

Hereinafter, a current breaking device according to an embodiment of the present invention and a battery pack including the same will be described in detail with reference to the accompanying drawings.

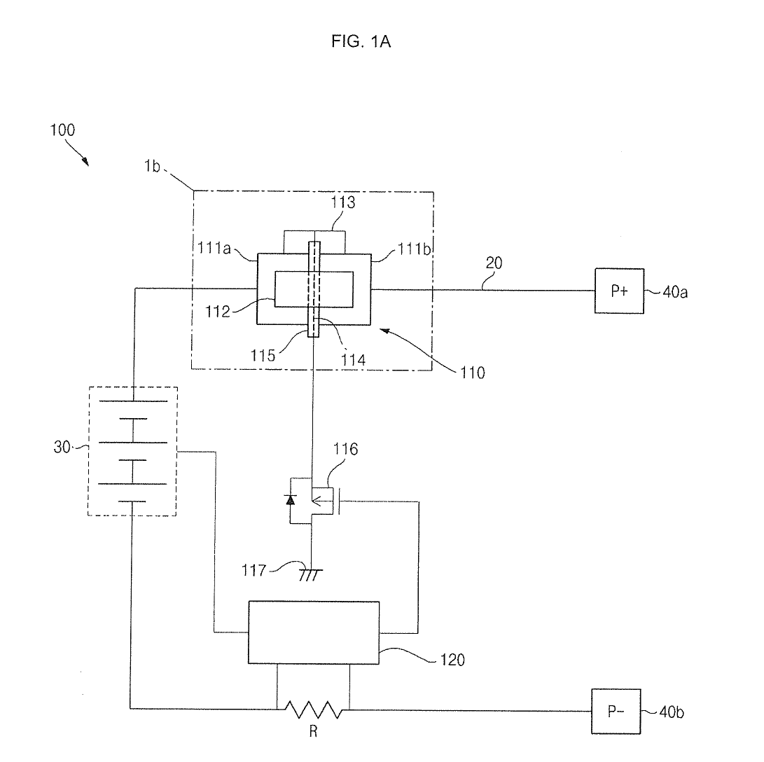

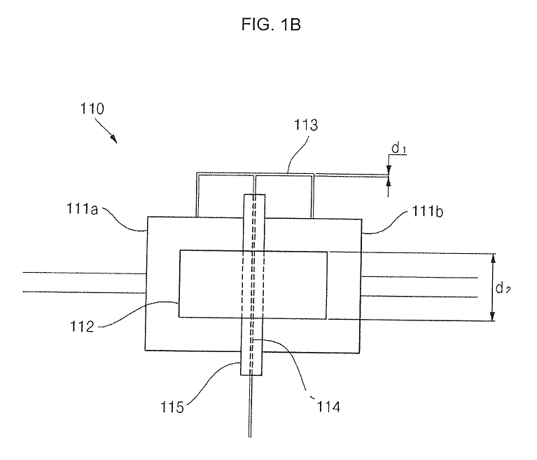

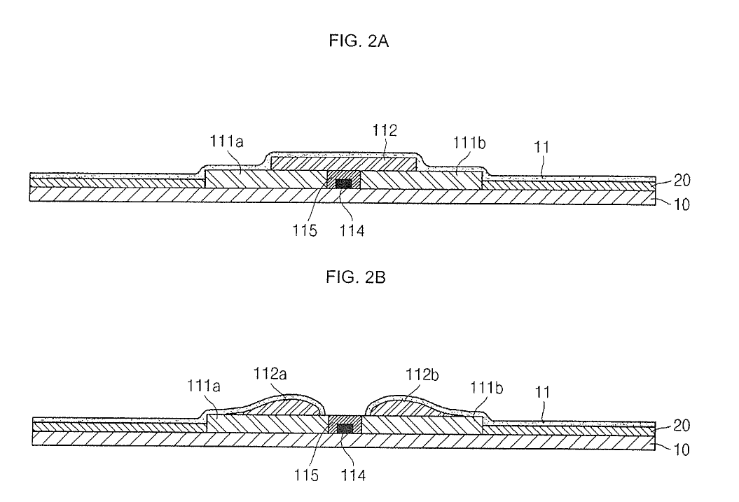

FIG. 1A is a schematic diagram illustrating a current breaking device according to one embodiment of the present invention and a battery pack including the same, and FIG. 1B is an enlarged view of a portion ‘1b’ of FIG. 1A, and FIGS. 2A and 2B are cross-sectional views illustrating states before and after an operation of the current breaking device shown in FIG. 1.

Referring to FIGS. 1A to 2B, the battery pack 100 of the current embodiment includes a current breaking device 110 and a controller 120.

The current breaking device 110 is formed directly on a circuit board 10, that is, an insulation (or insulating) layer, and is covered by a protection layer 11 (see, e.g., FIG. 2A) to protect the current breaking device 110 from the external environment. When an abnormal voltage is generated in a battery 30 or an abnormal current is generated along a high current path, the current breaking device 110 may shut down (or break) the high current path.

In some embodiments of the present invention, an “abnormal voltage” refers to an over-discharge state in which the voltage measured from the battery 30 is lower than approximately 3.0 V (a first voltage), or an over-charge state in which the voltage measured from the battery 30 is higher than approximately 4.2 V (a second voltage), and an “abnormal current” refers to an over-current state in which the current measured from the high current path is higher than a set or a predetermined current. However, the numerical values are provided only for illustration, but aspects of the present invention are not limited thereto. For example, the numerical values may vary in various manners according to the type of battery used with embodiments of the present invention or according to customer requests and design considerations.

The current breaking device 110 includes a first land 111a and a second land 111b, a fuse pattern 112, a current transfer pattern 113, a heat concentration unit 114, an insulation film 115 and a switch 116. Here, the first land 111a and the second land 111b, the fuse pattern 112, the current transfer pattern 113 and the heat concentration unit 114 are formed directly on the insulation layer of the circuit board 10.

The first land 111a and the second land 111b are formed patternwise (as used herein, “patternwise” refers to forming structures in the printed circuit board itself, e.g., by depositing and etching patterned layers using photoresistive layers) on the circuit board 10 using a metallic material capable of transferring current. In one embodiment, the first land 111a and the second land 111b are formed on the circuit board 10 in a copper foil pattern, which is the same as the wire pattern 20. This is for the purpose of reducing or minimizing the power loss caused while the power supplied through the wire pattern 20 passes through the first land 111a and the second land 111b.

The first land 111a and the second land 111b are spaced apart from each other and are respectively connected to the high current path.

The fuse pattern 112 is formed patternwise on the circuit board 10.

According to one embodiment of the present invention, the fuse pattern 112 is made of a low melting point metal capable of transferring the current.

Here, the melting temperature of the fuse pattern 112 is not particularly limited, but according to some embodiments is in a range of approximately 100 to 160 C, and, in some of those embodiments, in a range of approximately 130 to 150 C. For example, the fuse pattern 112 may be made of at least one material having a melting temperature in the range of approximately 100 to 160 C, selected from the group consisting of SnPb, SnAg, SnCu, SnAu, SnZn, SnZnBi, SnAgCu, SnAgBi and equivalents thereof, but embodiments of the present invention are not limited thereto.

In some embodiments of the present invention, the melting temperature in the range stated above substantially corresponds to resistance heat supplied from a heat concentration unit 114 to be described later, and the fuse pattern 112 may be melted by the resistance heat.

In one embodiment of the present invention, the fuse pattern 112 and the first land 111a are made of dissimilar metals, and the fuse pattern 112 and the second land 111b are made of dissimilar metals. Here, the first land 111a and the second land 111b have higher melting temperatures than the fuse pattern 112, so that the first land 111a and the second land 111b are not melted at the melting temperature of the fuse pattern 112. In addition, the first land 111a and the second land 111b may be made of at least one selected from the group consisting of Cu, Ni plated Cu, Pd plated Cu, and equivalents thereof, but embodiments of the present invention are not limited thereto.

According to one embodiment of the present invention, the fuse pattern 112 is formed on the first land 111a and the second land 111b and electrically connects the first land 111a and the second land 111b, thereby providing a high current path.

According to one embodiment of the present invention, the current transfer pattern 113 is made of a metallic material capable of transferring current and extends from the first land 111a and the second land 111b to be formed patternwise on the circuit board 10. Here, in one embodiment, the current transfer pattern 113 is made of the same material as the first land 111a and the second land 111b, to reduce or minimize the power loss caused while the power supplied to the first land 111a and the second land 111b passes through the current transfer pattern 113 by reducing contact resistance between the current transfer pattern 113 and the first land 111a and the second land 111b.

The current transfer pattern 113 electrically connects the first land 111a and the second land 111b. According to one embodiment, a width d1 and/or thickness of the current transfer pattern 113 is smaller than a width d2 and/or thickness of the fuse pattern 112, so that most of the current flows through the fuse pattern 112. In addition, in one embodiment, the current transfer pattern 113 is not physically connected to the fuse pattern 112. Further, in one embodiment, the width d1 and/or thickness of the current transfer pattern 113 are smaller than a width and/or thickness of the wire pattern 20.

The heat concentration unit 114 transfers the current and is formed as a resistor having a small width and generating heat using resistance heat (or resistive heating, ohmic heating, or Joule heating) derived from the current.

The heat concentration unit 114 is formed adjacent the fuse pattern 112. In one embodiment, the heat concentration unit 114 is formed between the first land 111a and the second land 111b and under (and adjacent) the fuse pattern 112 to be connected to the current transfer pattern 113.

Referring to FIG. 2B, when an abnormal voltage is generated in the battery 30 or an abnormal current is generated in the high current path, the heat concentration unit 114 generates heat using the resistance heat and melts the fuse pattern 112. When the fuse pattern 112 is melted, the high current path is shut down. Here, when the fuse pattern 112 melts, it is separated into a first fuse pattern 112a and a second fuse pattern 112b on the first land 111a and the second land 111b, respectively.

The resistance heat generated from the heat concentration unit 114 has a temperature high enough to melt the fuse pattern 112. Here, the heat concentration unit 114 is formed so as not to melt the first land 111a, the second land 111b, and the current transfer pattern 113. In addition, in one embodiment of the present invention, the resistance heat generated from the heat concentration unit 114 does not melt the insulation film 115.

The insulation film 115 is an electrical insulator that cuts off an electrical connection between the fuse pattern 112 and the heat concentration unit 114 and is formed between the fuse pattern 112 and the heat concentration unit 114. Here, the insulation film 115 surrounds the heat concentration unit 114 and insulates the first land 111a, the second land 111b, and the fuse pattern 112 from being connected (e.g., electrically connected) to the heat concentration unit 114.

The insulation film 115 is made of resin or plastic having high thermal conductivity to reduce or minimize the loss of heat in transmitting the resistance heat generated from the heat concentration unit 114 to the fuse pattern 112. For example, the insulation film 115 may be made of a thermally conductive polymer, thermally conductive particles, additives, and so on, but embodiments of the present invention are not limited thereto.

The switch 116 may be formed of a field effect transistor (FET) or a bipolar junction transistor (BJT). In some embodiments, a relay, instead of a transistor, may also be used as the switch 116.

The switch 116 may have a first electrode (or a first end) connected to the heat concentration unit 114, a second electrode (or second end) connected to a ground terminal 117, and a control electrode connected to the controller 120, respectively. According to one embodiment, the switch 116 is controlled by the controller 120 and connects the heat concentration unit 114 to the ground terminal 117 when an abnormal voltage is generated in the battery 30 or an abnormal current is generated in the high current path, thereby allowing the current to flow through the heat concentration unit 114 and causing the current breaking device 110 to shut down the high current path.

According to one embodiment of the present invention, the controller 120 is connected to a voltage sensor connected to the battery 30 and senses the voltage of the battery 30 and the current from a current sensor R connected to the controller 120 along the high current path. In addition, the controller 120 is connected to the control electrode of the switch 116 and operates the current breaking device 110 to shut down the high current path when an abnormal voltage is generated in the battery 30 or an abnormal current is generated in the high current path.

Hereinafter, a method of shutting down (or electrically disconnecting) the high current path by operating the current breaking device 110 according to one embodiment of the present invention will be described.

When the voltage of the battery 30 is out of a normal range or when the current of the high current path is higher than a current (e.g., a predetermined current or a particular current), the controller 120 controls the switch 116 to connect the heat concentration unit 114 to the ground terminal 117.

The heat concentration unit 114 generates heat at a constant temperature, and the heat is transmitted to the first land 111a, the second land 111b and the fuse pattern 112 through the insulation film 115.

The heat generated from the heat concentration unit 114 melts only the fuse pattern 112, and the fuse pattern 112 is divided into the first fuse pattern 112a and the second fuse pattern 112b on the first land 111a and the second land 111b, respectively.

In such a manner, the high current path is shut down (or electrically disconnected) by the fuse pattern 112 and only a small amount of current having passed through the current transfer pattern 113 flows through along the high current path. However, in some embodiments of the present invention, the current passing through the current transfer pattern 113 is a negligibly small amount, which is insufficient to drive an electronic device.

Therefore, in the battery pack 100 according to one embodiment, because a pattern formed in the circuit board 10, instead of a fuse, is used as an over-voltage and over-current preventing element of the high current path, the manufacturing cost of a battery pack can be reduced.

Next, a current breaking device according to another embodiment of the present invention and a battery pack including the same will be described.

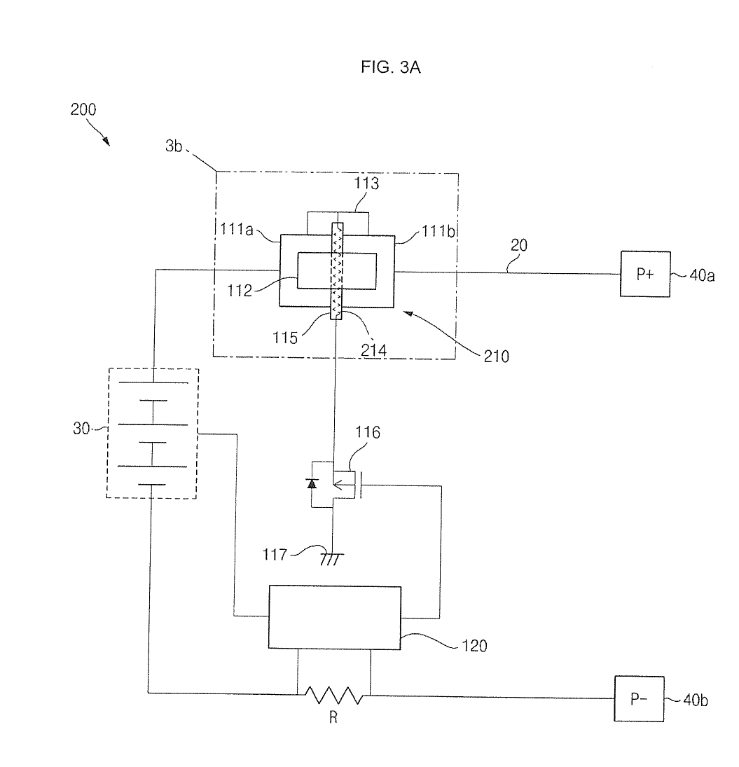

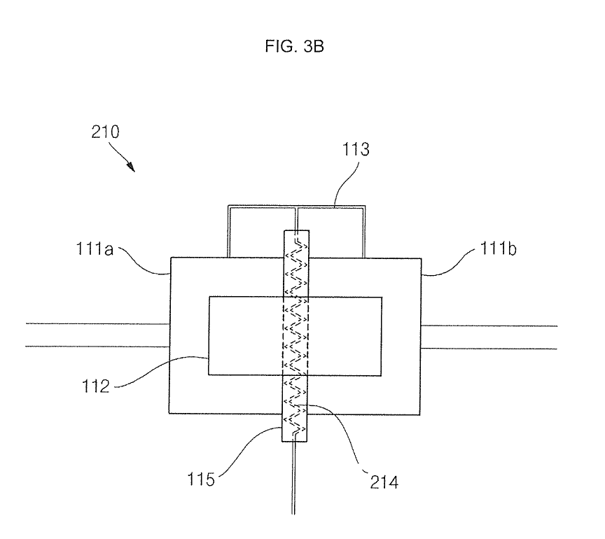

FIG. 3A is a schematic diagram illustrating a current breaking device according to another embodiment of the present invention and a battery pack including the same, and FIG. 3B is an enlarged view of a portion ‘3b’ of FIG. 3A.

Referring to FIGS. 3A and 3B, the battery pack 200 according to another embodiment of the present invention includes a current breaking device 210 and a controller 120.

The current breaking device 210 and the battery pack 200 including the same have a different configuration from that of the current breaking device 110 and the battery pack 100. Therefore, the following description of the battery pack 200 according to the current embodiment of the present invention will focus on the current breaking device 210. In addition, in the battery pack 200, like reference symbols indicate components the same as or similar to those of the battery pack 100 shown in FIG. 1A, and a repeated description thereof will be omitted.

The current breaking device 210 includes a heat concentration unit 214.

The heat concentration unit 214 is formed between the first land 111a and the second land 111b and under and adjacent the fuse pattern 112 to be connected to the current transfer pattern 113. Here, the heat concentration unit 214 has a substantially zigzag planar configuration to increase a heat-generating area. In addition to the zigzag planar configuration, the heat concentration unit 214 may have various suitable planar configurations to increase a heat-generating area.

The heat concentration unit 214 having an increased heat-generating area may transfer high-temperature heat to the fuse pattern 112 more rapidly than the linear heat concentration unit 114. Thus, the speed of shutting down the high current path in accordance with the abnormal voltage and the abnormal current is increased.

A current breaking device according to still another embodiment of the present invention and a battery pack including the same will be described.

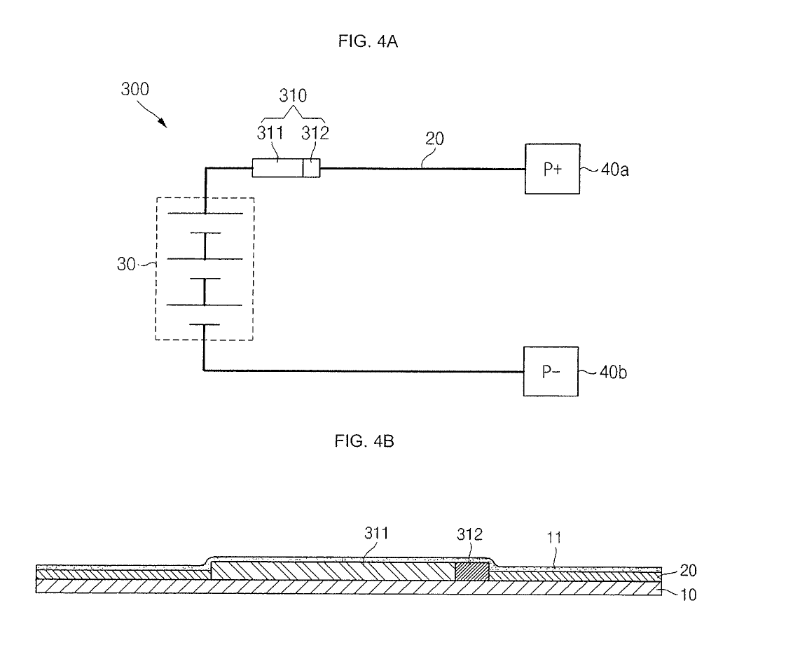

FIGS. 4A and 4B are a circuit diagram and a cross-sectional view schematically illustrating a current breaking device according to still another embodiment of the present invention, and a battery pack including the same.

Referring to FIGS. 4A and 4B, the battery pack 300 according to another embodiment of the present invention includes a current breaking device 310 including a heat generation unit 311 formed directly on an insulation layer of a circuit board 10 and a fuse pattern 312.

The current breaking device 310 is covered by a protection layer 11 to protect the current breaking device 310 from the external environment.

The heat generation unit 311 is a resistor formed patternwise on the circuit board 10. The heat generation unit 311 may have one side electrically connected to a wire pattern 20 at a side of a battery 30 and, when an over-current is generated in a high current path, may generate heat using resistance heat due to the over-current. The heat generation unit 311 may be made of a material having resistance higher than that of the wire pattern 20. For example, when the wire pattern 20 is made of copper (Cu), the heat generation unit 311 may be made of chrome (Cr), aluminum (Al), tungsten (W) or steel, but not limited thereto. The fuse pattern 312 is formed patternwise on the circuit board 10 using a metallic material capable of transferring current and may have one side connected in proximity to the heat generation unit 311 and the other side electrically connected to the wire pattern 20 at a side of a pack terminal 40a. Here, according to one embodiment, the fuse pattern 312 and the heat generation unit 311 are made of dissimilar metals. For example, the fuse pattern 312 may be made of at least one material selected from the group consisting of SnPb, SnAg, SnCu, SnAu, SnZn, SnZnBi, SnAgCu, SnAgBi and equivalents thereof, but embodiments of the present invention are not limited thereto.

When an over-current flows in the battery 30, the fuse pattern 312 melts the high current path using the resistance heat generated from the heat generation unit 311 connected in proximity to the fuse pattern 312, thereby shutting down (or electrically disconnecting) the high current path.

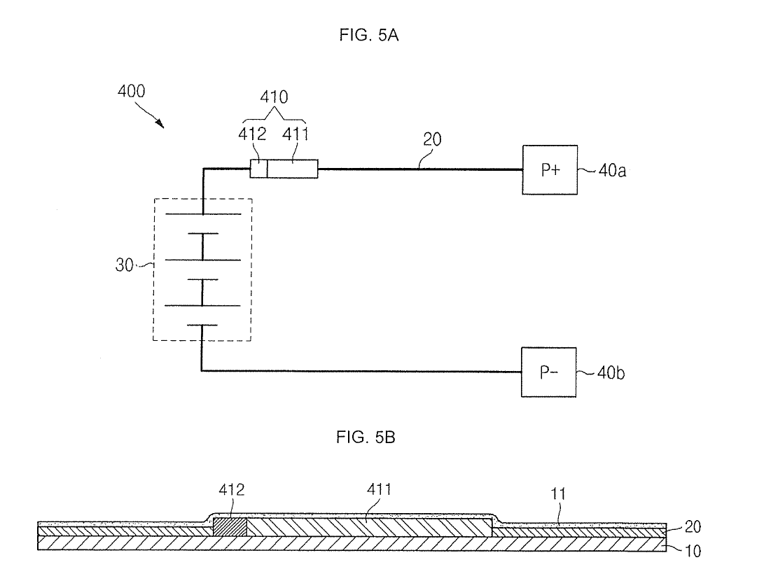

FIGS. 5A and 5B are a circuit diagram and a cross-sectional view schematically illustrating a current breaking device according to another embodiment of the present invention, and a battery pack including the same.

Referring to FIGS. 5A and 5B, the battery pack 400 according to another embodiment of the present invention includes a current breaking device 410 including a heat generation unit 411 formed directly on an insulation layer of a circuit board 10 and a fuse pattern 412.

The current breaking device 410 is covered by a protection layer 11 to protect the current breaking device 410 from the external environment.

The heat generation unit 411 is a resistor formed patternwise on the circuit board 10. The heat generation unit 411 may have one side electrically connected to a wire pattern 20 at a side of a pack terminal 40a and, when an over-current is generated in a high current path, may generate heat using resistance heat due to the over-current. The heat generation unit 411 may be made of a material having resistance higher than that of the wire pattern 20 and may be made of the same material as the heat generation unit 311. The fuse pattern 412 is formed patternwise on the circuit board 10 using a metallic material capable of transferring current and may have one side electrically connected to the wire pattern 20 at a side of a battery 30 and the other side connected in proximity to the heat generation unit 411a. In one embodiment of the present invention, the fuse pattern 412 and the heat generation unit 411 are made of dissimilar metals and may be made of the same material as the fuse pattern 312.

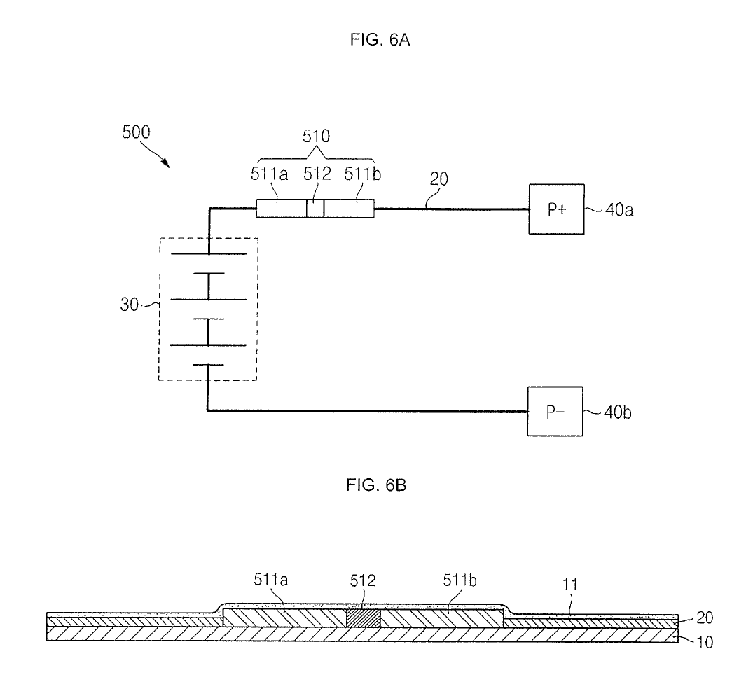

FIGS. 6A and 6B are a circuit diagram and a cross-sectional view schematically illustrating a current breaking device according to another embodiment of the present invention, and a battery pack including the same.

Referring to FIGS. 6A and 6B, the battery pack 500 according to another embodiment of the present invention includes a current breaking device 510 including a heat generation unit 511 (511a and 511b) formed on (e.g., directly on) an insulation layer of a circuit board 10 and a fuse pattern 512.

The current breaking device 510 is covered by a protection layer 11 to protect the current breaking device 510 from the external environment.

The heat generation unit 511 is divided into a first heat generation unit 511a and a second heat generation unit 511b.

The first heat generation unit 511a is a resistor formed patternwise on the circuit board 10. The first heat generation unit 511 may have one side electrically connected to a wire pattern 20 at a side of a battery 30 and, when an over-current is generated in a high current path, may generate heat using resistance heat due to the over-current. The first heat generation unit 511a may be made of a material having a resistance higher than that of the wire pattern 20 and may be made of the same material as the heat generation unit 311.

According to one embodiment of the present invention, the second heat generation unit 511b is a resistor formed patternwise on the circuit board 10. The second heat generation unit 511b may have one side electrically connected to a wire pattern 20 at a side of a pack terminal 40a and, when an over-current is generated in a high current path, may generate heat using resistance heat due to the over-current.

The second heat generation unit 511b may be made of a material having resistance higher than that of the wire pattern 20 and may be made of the same material as the heat generation unit 311.

According to one embodiment of the present invention, the fuse pattern 512 is formed patternwise on the circuit board 10 using a metallic material capable of transferring current and may be interposed between the first heat generation unit 511a and the second heat generation unit 511b. In one embodiment, the fuse pattern 512 and the heat generation unit 511 are made of dissimilar metals and may be made of the same material as the fuse pattern 312.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present disclosure as set forth in the following claims and equivalents thereof.

What is claimed is:

1. A current breaking device on a circuit board and connected to a battery, the current breaking device comprising:
a first land and a second land spaced apart from each other and electrically connected to a current path;
a fuse pattern on the first land and the second land and electrically connecting the first land and the second land;
a current transfer pattern electrically connecting the first land and the second land in parallel with the fuse pattern;
a heat concentration unit adjacent the fuse pattern and connected to the current transfer pattern;
an insulation film between the heat concentration unit and the fuse pattern; and
a switch electrically connected to the heat concentration unit.

2. The current breaking device as claimed in claim 1, wherein the switch is configured to turn on when a voltage of the battery is lower than a first voltage or higher than a second voltage or when a current of the current path is larger than a particular current.

3. The current breaking device as claimed in claim 2, wherein the heat concentration unit is configured to generate resistance heat to melt the fuse pattern to electrically disconnect the current path.

4. The current breaking device as claimed in claim 1, wherein the fuse pattern is made of a first material, and the first land and the second land are made of a second material, respectively, the first material being different from the second material.

5. The current breaking device as claimed in claim 1, wherein the first land, the second land, and the current transfer pattern have higher melting temperatures than the fuse pattern.

6. The current breaking device as claimed in claim 1, wherein the fuse pattern is wider than the current transfer pattern.

7. The current breaking device as claimed in claim 1, wherein the heat concentration unit has a zigzag plane.

8. The current breaking device as claimed in claim 1, wherein the insulation film is thermally conductive and is made of resin or plastic.

9. The current breaking device as claimed in claim 1, wherein the insulation film surrounds the heat concentration unit and is interposed between the first land and the second land.

10. The current breaking device as claimed in claim 1, wherein the switch has a first electrode electrically connected to the heat concentration unit and a second electrode electrically connected to a ground terminal.

11. A current breaking device comprising:
a heat generation unit formed patternwise in a current path disposed on a circuit board and comprising a resistor; and
a fuse pattern adjacent the heat generation unit and formed patternwise in the current path disposed on the circuit board, the fuse pattern being electrically connected in series with the heat generation unit in the current path.

12. The current breaking device as claimed in claim 11, wherein the heat generation unit is configured to generate heat using resistive heating derived from a current flowing through the heat generation unit.

13. The current breaking device as claimed in claim 12, wherein the heat generation unit is configured to melt the fuse pattern using the resistive heating.

14. The current breaking device as claimed in claim 11, wherein the heat generation unit is made of a first material and the fuse pattern is made of a second material, the first material being different from the second material.

15. The current breaking device as claimed in claim 13, wherein the heat generation unit is coupled between a battery and the fuse pattern and the fuse pattern is coupled between the heat generation unit and a terminal or the heat generation unit is coupled between the terminal and the fuse pattern and the fuse pattern is coupled between the heat generation unit and the battery.

16. The current breaking device as claimed in claim 13, wherein the heat generation unit comprises a first heat generation unit and a second heat generation unit, and the fuse pattern is between the first heat generation unit and the second heat generation unit.

17. A battery pack comprising:
a rechargeable battery; and
a protective circuit configured to operate when a voltage of the battery is lower than a first voltage or higher than a second voltage or when a current greater than a particular current is detected,
wherein the protective circuit comprises:
a circuit board comprising a wire pattern;
a current breaking device electrically connected to the wire pattern and formed patternwise on the circuit board; and
a controller configured to control the current breaking device.

18. The battery pack as claimed in claim 17, wherein the current breaking device comprises:
a first land and a second land spaced apart from each other and connected to a current path;
a fuse pattern formed on the first land and the second land and electrically connecting the first land to the second land;
a current transfer pattern electrically connecting the first land and the second land in parallel with the fuse pattern;
a heat concentration unit formed adjacent the fuse pattern and electrically connected to the current transfer pattern;
an insulation film between the heat concentration unit and the fuse pattern; and
a switch having a first electrode connected to the heat concentration unit and a second electrode connected to a ground terminal and configured to be turned on by the controller.

19. The battery pack as claimed in claim 18, wherein the current breaking device is configured to turn on the switch to connect the heat concentration unit to the ground terminal, so that resistive heating derived from the current flowing through the current breaking device is generated.

20. The battery pack as claimed in claim 17, wherein the current breaking device is configured to melt the fuse pattern using the resistive heating to electrically disconnect the current path of the wire pattern.
